(19) United States
(12) Patent Application Publication
(10) Pub. No.: US 2015/0034926 A1
(43) Pub. Date: Feb. 5, 2015

(54) ORGANIC ELECTROLUMINESCENCE ELEMENT

(71) Applicant: Panasonic Corporation, Osaka (JP)

(72) Inventors: Manabu Nakata, Osaka (JP); Takeyuki Yamaki, Nara (JP); Masahiro Nakamura, Osaka (JP); Masahito Yamana, Hyogo (JP)

(73) Assignee: Panasonic Corporation, Osaka (JP)

(21) Appl. No.: 14/374,138

(22) PCT Filed: Jan. 23, 2013
(86) PCT No.: PCT/JP2013/000325

§ 371 Date: Jul. 23, 2014

(30) Foreign Application Priority Data
Jan. 31, 2012 (JP) 2012-018158

(51) Int. Cl. H01L 51/52

(52) U.S. Cl. CPC H01L 51/5256; H01L 51/5203
USPC 257/40

(57) ABSTRACT

The organic electroluminescence element includes a functional layer which is interposed between the first electrode and the second electrode and includes a light-emitting layer. The second electrode includes at least an electrically conductive polymer layer which is in contact with the functional layer and has a light transmissive property. The organic electroluminescence element includes: a substrate; a sealing substrate with a light transmissive property; a transparent protection layer covering an element part including a stack of the first electrode, the functional layer and the second electrode; and a resin layer which is interposed between the transparent protection layer and the sealing substrate and has a light transmissive property.

### TECHNICAL FIELD

The present invention relates to organic electroluminescence elements.

### BACKGROUND ART

Recently, organic electroluminescence elements are attracting attention as next-generation light emitting devices because of various advantages that such organic electroluminescence elements enable surface emission, can be mercury-free, can operate at low temperature, can be made at low cost, can be lighter, and can be flexible.

As such organic electroluminescence elements, there has been proposed an organic electroluminescence light-emitting device having a structure shown in FIG. 6 (document 1 [JP 2008-181832 A]), for example.

In this organic electroluminescence light-emitting device, a transparent conductive layer 102 is placed on a surface of a light transmissive substrate 101, an organic light-emitting layer 103 is placed on the transparent conductive layer 102, and a cathode layer 104 is placed on the organic light-emitting layer 103. Further, this organic electroluminescence light-emitting device includes a protective encapsulating layer 107 to encapsulate a stack 106 of the organic light-emitting layer 103 and the cathode layer 104, and a hygroscopic agent-containing encapsulating layer 108 to encapsulate the protective encapsulating layer 107. Further, in this organic electroluminescence light-emitting device, a moisture-proof layer 109 is disposed on the outside of the hygroscopic agent-containing encapsulating layer 108, and the moisture-proof layer 109 is bonded to the light transmissive substrate 101 via an adhesive layer 110. The hygroscopic agent-containing encapsulating layer 108 is made by applying base resin containing hygroscopic agent to an outer surface of the protective encapsulating layer 107.

The document 1 discloses that the hygroscopic agent is preferably a compound which has a function of absorbing moisture and is capable of being solid even when absorbing moisture. Particularly, preferred examples of the hygroscopic agent may include calcium oxide, barium oxide, silica gel and the like. In the embodiment 1 disclosed in the document 1, the transparent conductive layer 102 is formed by patterning an ITO film prepared by sputtering on the light transmissive substrate 101. Further, the cathode layer 104 is formed by deposition of Al.

In the organic electroluminescence element having the structure shown in FIG. 6, light produced in the organic light-emitting layer 103 emerges outside through the light transmissive substrate.

In contrast, there has been proposed a top emission type organic electroluminescence element having a structure shown in FIG. 7 (document 2 [JP 2006-331694 A]), for example. In this organic electroluminescence element, one electrode (cathode) 201 is placed on a surface of a substrate 204, and a light-emitting layer 203 is placed on a surface of the electrode 201 with an electron injection/transport layer 205 in between, and the other electrode (anode) 202 is placed on the light-emitting layer 203 with a hole injection/transport layer 206 in between. Further, this organic electroluminescence element includes a cover member 207 connected to the surface of the substrate 204. Therefore, in this organic electroluminescence element, light produced in the light-emitting layer 203 is emitted outside through the electrode 202 formed as a light transmissive electrode and the cover member 207 made of transparent material.

Examples of material of the electrode 201 with light reflectivity may include Al, Zr, Ti, Y, Sc, Ag, and In. Examples of material of the electrode 202 serving as a light transmissive electrode may include indium tin oxide (ITO) and indium zinc oxide (IZO).

According to the disclosure of the document 2, in some cases a desiccant may be placed inside the cover member 207 in order to suppress generation and development of non-luminous area. Such a desiccant preferably has a light transmissive property. However, depending on a size or a location of a desiccant, this desiccant may be opaque.

There has been also proposed a top emission type organic electroluminescence element having a structure shown in FIG. 8 (document 3 [JP 2008-293676 A]).

This organic electroluminescence element has such a structure that a reflective electrode 320, an organic EL layer 330, an electron injection layer 335 and a transparent electrode 340 are stacked on a surface of a substrate 310. Further, in this organic electroluminescence element, a cover substrate 360 is bonded to the surface of the substrate 310 with an encapsulating member 390 in between.

Further, this organic electroluminescence element includes a transparent protection layer 350 formed so as to encapsulate the reflective electrode 320, the organic EL layer 330, the electron injection layer 335 and the transparent electrode 340.

In this respect, the reflective electrode 320 is formed of a layered film of an Al film prepared by a vapor deposition method and an ITO film prepared by sputtering, for example. Further, the organic EL layer 330 is formed by a printing method, for example. The transparent electrode 340 is formed on the organic EL layer 330 by sputtering, a CVD method, a vapor deposition method or the like. The transparent electrode 340 is made of a conductive oxide such as SnO₂, In₂O₃, ITO, IZO, and ZnO:Al. The document 3 discloses that material of the transparent protection layer 350 preferably has a gas barrier property and can be inorganic material (e.g., inorganic oxide and inorganic nitride) such as SiO_{X}, SiN_{X}, SiN_{X}O_{Y}, AlO_{X}, TiO_{X}, TaO_{X}, and ZnO_{X}.

### SUMMARY OF INVENTION

### Technical Problem

It is generally known that, in top emission type organic electroluminescence elements, to improve light-outcoupling efficiency in a thin film mode, it is necessary to employ a structure in which a space between a light transmissive electrode and an encapsulating member is filled with transparent material.

However, the present inventors have found that, in a case where electrically conductive polymer material is used for a transparent electrode, the transparent electrode is likely to be damaged in a process of filling the space between the light transmissive electrode and the encapsulating member with the transparent material such as resin and thus properties of elements are likely to be greatly deteriorated.

In view of the above insufficiency, the present invention has aimed to propose an organic electroluminescence element in which an electrode allowing light transmission is made of electrically conductive polymer material and nevertheless light-outcoupling efficiency and reliability can be improved.

### Solutions to Problem

The organic electroluminescence element in accordance with the present invention includes a substrate, a first electrode disposed on/above a surface of the substrate, a second electrode facing an opposite side of the first electrode from the surface of the substrate, and a functional layer which is interposed between the first electrode and the second electrode and includes at least a light-emitting layer. The organic electroluminescence element is configured to allow light to emerge from the second electrode. The second electrode includes at least an electrically conductive polymer layer which is in contact with the functional layer and has a light transmissive property. The organic electroluminescence element further includes a sealing substrate which is opposite the surface of the substrate and has a light transmissive property, a transparent protection layer covering an element part which has a stack of the first electrode, the functional layer and the second electrode, and a resin layer which is interposed between the transparent protection layer and the sealing substrate and has a light transmissive property.

In a preferred aspect of this organic electroluminescence element, the transparent protection layer has a thickness in a range of 10 nm to 100 nm inclusive.

In a preferred aspect of this organic electroluminescence element, the resin layer has a refractive index greater than a refractive index of the electrically conductive polymer layer.

In a preferred aspect of this organic electroluminescence element, the transparent protection layer is formed by a coating method.

In a preferred aspect of this organic electroluminescence element, the transparent protection layer is made of polymeric organic material with a light transmissive property.

In a preferred aspect of this organic electroluminescence element, the transparent protection layer is made of inorganic material with a light transmissive property.

In a preferred aspect of this organic electroluminescence element, the second electrode includes a patterned electrode. The patterned electrode includes: an electrode part covering a surface on an opposite side of the electrically conductive polymer layer from the functional layer; and an opening formed in the electrode part such that the surface of the electrically conductive polymer layer is exposed through the opening. The electrode part of the patterned electrode is made of electrode material including metal powder and an organic binder.

In a preferred aspect of this organic electroluminescence element, the transparent protection layer has a refractive index greater than at least one of a refractive index of the light-emitting layer and a refractive index of the electrically conductive polymer layer.

### Advantageous Effects of Invention

The organic electroluminescence element in accordance with the present invention has such a structure that an electrode allowing light transmission is made of electrically conductive polymer material and nevertheless can improve the light-outcoupling efficiency and reliability.

### BRIEF DESCRIPTION OF DRAWINGS

FIG. 1 is a schematic sectional view illustrating the organic electroluminescence element according to the embodiment.

FIG. 2 is a schematic plan view illustrating the patterned electrode of the organic electroluminescence element according to the embodiment.

FIG. 3 is a schematic sectional view illustrating the primary part of the organic electroluminescence element according to the embodiment.

FIG. 4 is a schematic plan view illustrating another example of the structure of the patterned electrode of the organic electroluminescence element according to the embodiment.

FIG. 5 is a schematic plan view illustrating another example of the structure of the patterned electrode of the organic electroluminescence element according to the embodiment.

FIG. 6 is a sectional view illustrating one example of a conventional organic electroluminescence light-emitting device.

FIG. 7 is a schematic sectional view illustrating one example of a conventional top emission type organic electroluminescence element.

FIG. 8 is a schematic sectional view illustrating another example of a conventional top emission type organic electroluminescence element.

### DESCRIPTION OF EMBODIMENTS

As mentioned above, in top emission type organic electroluminescence elements, it is known that the space between the light transmissive electrode and the encapsulating member is filled with the transparent material to improve the light-outcoupling efficiency in the thin film mode. It is preferable that the transparent material has a refraction index greater than that of material for a transparent electrode serving as a light transmissive electrode. With use of such material, in the top emission type organic electroluminescence element, it is possible to prevent total reflection at the interface between the transparent electrode and the medium made of transparent material and thus the light-outcoupling efficiency can be improved. Resin material is used as the transparent material because it is easy to manufacture layers made of the transparent material.

However, the present inventors have found that, in such a structure that electrically conductive polymer material is used for an electrode allowing light transmission, the electrode constituted by the electrically conductive polymer layer would be damaged due to presence of transparent material in the process of manufacturing and thus significant deterioration of the properties of the element is likely to occur. It is presumed that this problem is caused by composition of the resin material. To solve this problem, it is necessary to design the resin material in consideration of both improvement of a refractive index of the resin material and reduction of influence of the resin material on the electrically conductive polymer layer, and, as a result, material design becomes extremely difficult.

With respect to the above problem, the present inventors considered such a structure that a transparent protection layer is placed on a surface of the electrode formed of the electrically conductive polymer such that material of the electrically conductive polymer and material of the resin material can be designed independently from each other and have achieved the present invention. Note that, differently from a structure including the transparent protection layer 350 functioning as a gas barrier layer for preventing negative effect of outside moisture as disclosed in document 3, the present invention solves a new problem specific to such a structure that the electrically conductive polymer is used as material of the electrode allowing light to emerge from the electrode.

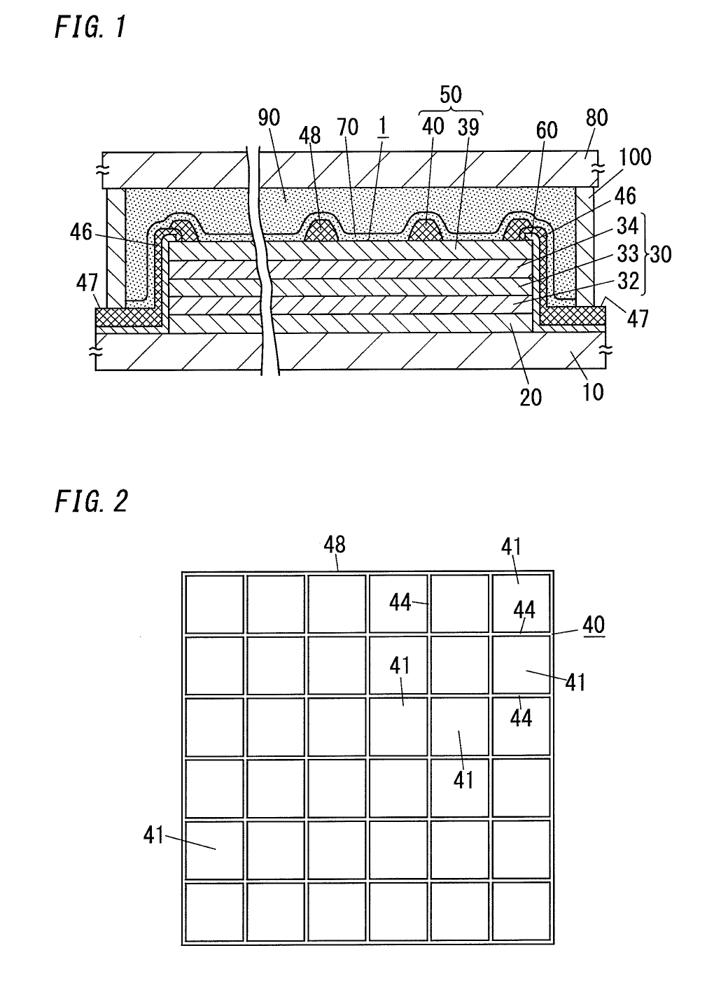

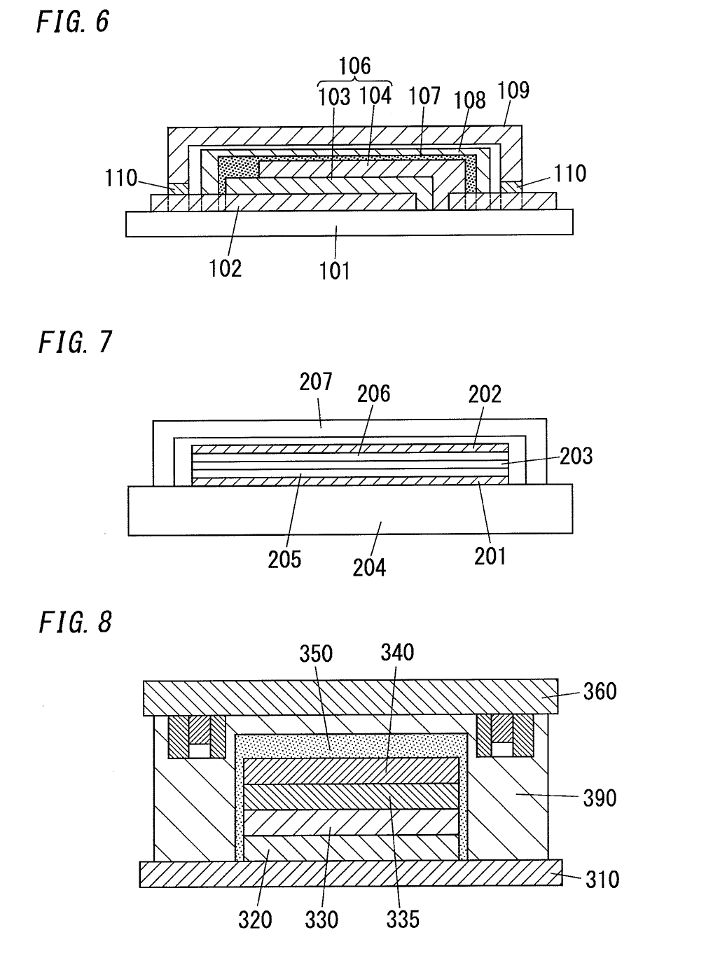

The following explanations referring to FIG. 1 to FIG. 6 are made to an organic electroluminescence element of the present embodiment.

The organic electroluminescence element includes: a substrate 10; a first electrode 20 disposed on/above a surface of the substrate 10; a second electrode 50 facing an opposite side of the first electrode 20 from the surface of the substrate 10; and a functional layer 30 which is interposed between the first electrode 20 and the second electrode 50 and includes at least a light-emitting layer.

The organic electroluminescence element of the present embodiment is configured to allow light to emerge from the second electrode 50. That is, the organic electroluminescence element of the present embodiment is a top emission type organic electroluminescence element.

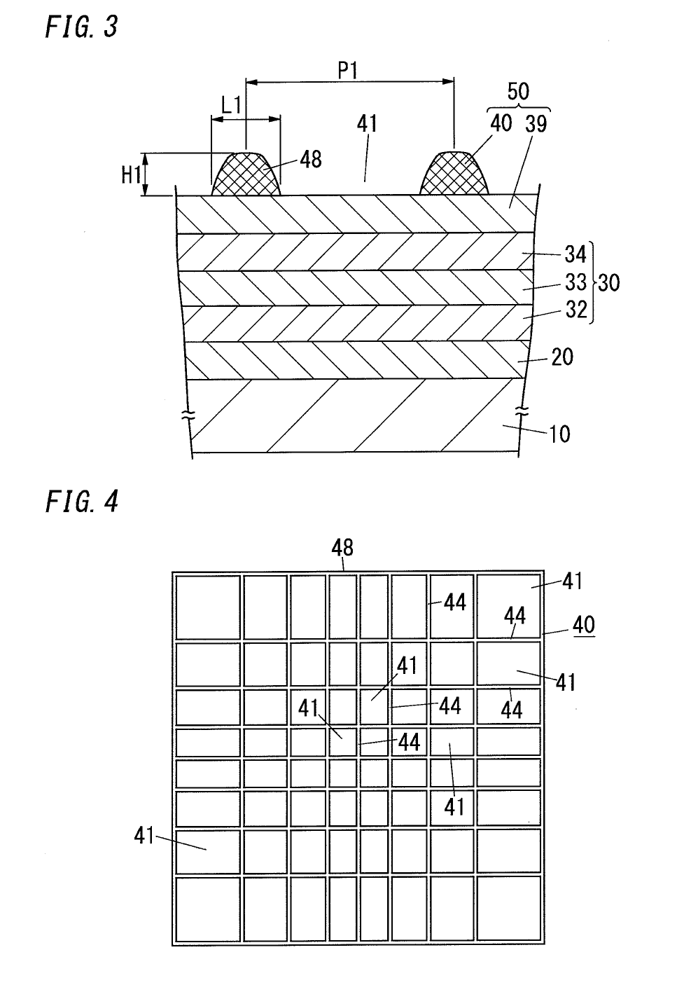

It is sufficient that the second electrode 50 includes at least an electrically conductive polymer layer 39 which is in contact with the functional layer 30 and has a light transmissive property. Thereby, in the organic electroluminescence element, it is possible to allow light to emerge from the second electrode 50. In the example shown in FIG. 1, the second electrode 50 includes a patterned electrode 40 as well as the electrically-conductive polymer layer 39. The patterned electrode 40 is located on an opposite side of the electrically conductive polymer layer 39 from the functional layer 30 and includes at least one opening 41 (see FIGS. 2 and 3) to transmit light from the functional layer 30. The patterned electrode 40 includes an electrode part 48 covering a surface on the opposite side of the electrically conductive polymer layer 39 from the functional layer and the opening 41 formed in the electrode part 48 such that the surface of the electrically conductive polymer layer 39 is exposed through the opening 41. Thereby, in the organic electroluminescence element, the second electrode 50 includes the patterned electrode 40 and nevertheless the organic electroluminescence element can allow light to emerge from the second electrode 50. However, in a case where a voltage drop caused by the resistance of the electrically-conductive polymer layer 39 is ignorable, the second electrode 50 of the organic electroluminescence element may include the electrically-conductive polymer layer 39 only. Note that, for example, if in-plane evenness in luminance of the organic electroluminescence element meets intended specifications, the voltage drop caused by the resistance of the electrically-conductive polymer layer 39 can be ignored.

Further, the organic electroluminescence element includes a sealing substrate 80 which is opposite the surface of the substrate 10 and has a light transmissive property. Also, the organic electroluminescence element includes a frame part 100 which is interposed between a periphery of the substrate 10 and a periphery of the sealing substrate 80 and has a frame shape (rectangular frame shape in the present embodiment).

Further, the organic electroluminescence element includes: a transparent protection layer 70 covering an element part 1 which has a stack of the first electrode 20, the functional layer 30 and the second electrode 50; and a resin layer 90 which is interposed between the transparent protection layer 70 and the sealing substrate 80 and has a light transmissive property. The transparent protection layer 70 is made of polymeric organic material with a light transmissive property.

In the organic electroluminescence element, a part (not shown) of the first electrode 20 which does not overlap a stack of the functional layer 30 and the second electrode 50 may serve as a first terminal part, or the first terminal part connected to the first electrode 20 through a first extended wire may be added. Further, in the organic electroluminescence element, the first terminal part may be an exposed part of the substrate 10 made of a metal plate or metal foil. The organic electroluminescence element includes a second terminal part 47 which is electrically connected to the second electrode 50 via a second extended wire 46. The second extended wire 46 and the second terminal part 47 are placed on the surface of the substrate 10, but the structures of the second extended wire 46 and the second terminal part 47 are not limited thereto. In a case where the substrate 10 is made of metal foil, an end of the second terminal part 47 may be bent toward a direction opposite to the sealing substrate 80 along with an end of a below-described insulating layer 60 and an end of the substrate 10. Further, in the organic electroluminescence element, the above insulating layer 60 is formed continuously to extend over the surface of the substrate 10, a side surface of the first electrode 20, a side surface of the functional layer 30, and a periphery of a surface close to the second electrode 50 of the functional layer 30. Thereby, in the organic electroluminescence element, the second extended wire 46 is electrically insulated from the functional layer 30 and the first electrode 20 by the insulating layer 60.

The following is a detailed explanation made to each component of the organic electroluminescence element.

The substrate 10 is formed into a rectangular shape in a plan view. Note that, the shape of the substrate 10 in a plan view is not limited to a rectangular shape, but may be a polygonal shape other than the rectangular shape, a circular shape or the like.

The substrate 10 is formed of a rigid glass substrate, but is not limited thereto. For example, the substrate 10 may be of a rigid or flexible plastic plate, a rigid metal plate, or flexible metal foil. Examples of materials of the glass substrate may include soda-lime glass and non-alkali glass. Examples of materials of the plastic plate may include polyethylene terephthalate, polyethylene naphthalate, polyether sulfone, and polycarbonate. Examples of materials of the metal plate and the metal foil may include metal such as copper, stainless steel, aluminum, nickel, tin, lead, gold, silver, iron, titanium, and alloy including at least one type of the above-described metal. As to the plastic plate, in order to suppress permeation of water, it is preferred to use a plastic plate having a surface coated with a film such as an SiON film and an SiN film. Note that the substrate 10 may be rigid or flexible. Further, in the organic electroluminescence element, the substrate 10 is not limited to a substrate such as a transparent glass substrate and a transparent plastic substrate, but the substrate 10 can be made of material which may have relatively high mechanical strength, be inexpensive, and have a gas barrier property, chemical resistance, and heat resistance. Further, in a case where the substrate 10 is made of material having electrical conductivity such as a metal plate and metal foil, the substrate 10 may serve as a part of the first electrode 20 or as the first electrode 20 per se.

In a case where the substrate 10 is formed of a glass substrate, unevenness of the surface of the substrate 10 may cause a leak current of the organic electroluminescence element (i.e. may cause deterioration of the organic electroluminescence element). Therefore, in the case where a glass substrate is used for the substrate 10, it is preferred to prepare a glass substrate for device formation which is highly-polished such that the surface has sufficiently small roughness. With regard to the surface roughness of the surface of the substrate 10, an arithmetic average roughness Ra defined in JIS B 0601-2001 (ISO 4287-1997) is preferably 10 nm or less and is more preferably several nm or less. In contrast, when a plastic plate is used for the substrate 10, it is possible to obtain a substrate which has an arithmetical average roughness Ra of the surface that is several nm or less, at lower cost, without performing highly precise polishing particularly.

In the organic electroluminescence element of the present embodiment, the first electrode 20 serves as a cathode and the second electrode 50 serves as an anode. In this case, a first carrier injected from the first electrode 20 to the functional layer 30 is an electron, and a second carrier injected from the second electrode 50 to the functional layer 30 is a hole. The functional layer 30 includes a light-emitting layer 32, a second carrier transport layer 33 and the second carrier injection layer 34 which are arranged in order from the first electrode 20. In this respect, the carrier transport layer 33 and the carrier injection layer 34 serve as a hole transport layer and a hole injection layer, respectively. Note that, in a case where the first electrode 20 serves as an anode and the second electrode 50 serves as a cathode, an electron transport layer may be used as the carrier transport layer 33 and an electron injection layer may be used as the carrier injection layer 34.

A structure of the above functional layer 30 is not limited to the example shown in FIG. 1, but at least one of a first carrier injection layer and a first carrier transport layer may be placed between the first electrode 20 and the light-emitting layer 32, and an interlayer may be placed between the light-emitting layer 32 and the carrier transport layer 33. In a case where the first electrode 20 serves as a cathode and the second electrode 50 serves as an anode, the first carrier injection layer serves as an electron injection layer and the first carrier transport layer serves as an electron transport layer.

Further, it is sufficient that the functional layer 30 includes at least the light-emitting layer 32 (i.e., the functional layer 30 may include only the light-emitting layer 32). Components other than the light-emitting layer 32, namely the first carrier injection layer, the first carrier transport layer, the interlayer, the second carrier transport layer 33, the second carrier injection layer 34 and the like are optional. The light-emitting layer 32 may have either a single-layer structure or a multilayer structure. In a case where white light is required, the light-emitting layer 32 may be doped with three types of dye materials, i.e. red, green, blue dyes; may have a stack of a blue light-emitting layer with a hole transport property, a green light-emitting layer with an electron transport property and a red light-emitting layer with an electron transport property; or may have a stack of a blue light-emitting layer with an electron transport property, a green light-emitting layer with an electron transport property and a red light-emitting layer with an electron transport property.

Examples of materials of the light emitting layer 32 include Poly(p-phenylenevinylene) derivative, polythiophene derivative, poly(ρ-phenylene) derivative, polysilane derivative, and polyacetylene derivative; polymerized compound of such as polyfluorene derivative, polyvinyl carbazole derivative, chromoporic material, and luminescence material of metal complexes; anthracene, naphthalene, pyrene, tetracene, coronene, perylene, phthaloperylene, naphthaloperylene, diphenylbutadiene, tetraphenylbutadiene, coumalin, oxadiazole, bisbenzoxazoline, bisstyryl, cyclopentadiene, coumalin, oxadiazol, bis benzo ide quinazoline, Bisusuchiriru, cyclopentadiene, quinoline-metal complex, tris(8-hydroxyquinolinate)aluminum complex, tris(4-methyl-8-quinolinate)aluminum complex, tris(5-phenyl-8-quinolinate)aluminum complex, aminoquinoline-metal complex, benzoquinoline-metal complex, tri-(p-terphenyl-4-yl)amine, pyrane, quinacridone, rubrene and their derivatives; 1-aryl-2,5-di(2-thienyl)pyrrole derivative, distyrylbenzene derivative, styrylarylene derivative, styrylamine derivative, and various compounds containing a group (radical) that is formed of the above-listed luminescent material. The material of the light emitting layer 32 is not limited to compounds based on fluorescent dye listed above, and examples of materials of the light emitting layer 32 include so-called phosphorescent material such as iridium complex, osmium complex, platinum complex, europium complex, and compounds or polymer molecules containing one of these complexes. One or plural of these materials can be selected and used as necessary. The light-emitting layer 32 is preferably formed into a film shape by a wet process such as a coating method (e.g., a spin coating method, spray coating method, dye coating method, gravure printing method, and screen printing method). However, the light-emitting layer 32 may be formed into a film shape by a dry process such as a vacuum vapor deposition method and a transfer method as well as by the coating method.

Examples of material for the electron injection layer include metal fluorides (e.g., lithium fluoride and magnesium fluoride), metal halide compounds (e.g., metal chlorides typified by sodium chloride and magnesium chloride) and oxides such as titanium, zinc, magnesium, calcium, barium and strontium. In the case where these materials are used, the electron injection layer can be formed by a vacuum vapor deposition method. Also, the electron injection layer can be made of an organic semiconductor material doped with dopant (such as alkali metal) for promoting electron injection. In the case where such material is used, the electron injection layer can be formed by a coating method.

Material of the electron transport layer can be selected from the group of compounds that allow electron transport. Examples of such types of compounds may include a metal complex that is known as electron transporting material (e.g., Alq₃), and compounds having a heterocycle (e.g., phenanthroline derivatives, pyridine derivatives, tetrazine derivatives, and oxadiazole derivatives), but are not limited thereto, and any electron transport material that is generally known can be used.

Examples of material for the electron injection layer include metal fluorides (e.g., lithium fluoride and magnesium fluoride), metal halide compounds (e.g., metal chlorides typified by sodium chloride and magnesium chloride) and oxides such as titanium, zinc, magnesium, calcium, barium and strontium. In the case where these materials are used, the electron injection layer can be formed by a vacuum vapor deposition method. Also, the electron injection layer can be made of an organic semiconductor material doped with dopant (such as alkali metal) for promoting electron injection. In the case where such material is used, the electron injection layer can be formed by a coating method.

The hole transport layer can be made of low-molecular material or polymeric material having a comparatively low LUMO (Lowest Unoccupied Molecular Orbital) level. Examples of material of the hole transport layer include polymer containing aromatic amine such as polyarylene derivative containing aromatic amine on the side chain or the main chain, e.g., polyvinyl carbazole (PVCz), polypyridine, polyaniline and the like. However, the material of the hole transport layer is not limited thereto. Note that, examples of material of the hole transport layer may include 4,4′-bis[N4naphthyl)-N-phenyl-amino]biphenyl (alpha-NPD), N,N′-bis(3-methylphenyl)-(1,1′-biphenyl)-4,4′-diamine (TPD), 2-TNATA, 4,4′,4″-tris(N-(3-methylphenyl)N-phenylamino)triphenylamine (MTDATA), 4,4′-N,N′-dicarbazolebiphenyl (CBP), Spiro-NPD, spiro-TPD, spiro-TAD, TNB, and TFB(Poly[(9,9-dioctylfluorenyl-2,7-diyl)-co-(4,4′-(N-(4-sec-butylphenyl))diphenyl amine)].

Examples of material of the hole injection layer include organic material containing thiophene, triphenylmethane, hydrazoline, amylamine, hydrazone, stilbene, triphenylamine and the like. In detail, examples of materials of the hole injection layer include aromatic amine derivative such as polyvinyl carbazole, polyethylenedioxythiophene:polystyrenesulfonate (PEDOT:PSS), TPD and the like. These materials can be used alone or in combination of two or more. The hole injection layer mentioned above can be formed into a film shape by a wet process such as a coating method (e.g., a spin coating method, spray coating method, dye coating method, and gravure printing method).

It is preferable that the interlayer has a carrier blocking function (in this configuration, an electron blocking function) of serving as a first carrier barrier (in this configuration, an electron barrier) which suppresses leakage of the first carrier (in this configuration, an electron) from the light-emitting layer 32 to the second electrode 50. Further, it is preferable that the interlayer has a function of transporting the second carrier (in this configuration, a hole) to the light-emitting layer 32, and a function of preventing quenching of an excited state of the light-emitting layer 32. Note that, in the present embodiment, the interlayer serves as an electron blocking layer which suppresses leakage of an electron from the light-emitting layer 32.

In the organic electroluminescence element, with providing the interlayer, it is possible to improve the luminous efficiency and prolong the lifetime. Examples of material of the interlayer include polyallylamine and derivative thereof, polyfluorene and derivative thereof, polyvinyl carbazole and derivative thereof, and triphenyldiamine derivative. The interlayer as mentioned above can be formed into a film shape by a wet process such as a coating method (e.g., a spin coating method, spray coating method, dye coating method, and gravure printing method).

The cathode is an electrode for injecting an electron (first carrier) treated as a first charge into the functional layer 30. In the case where the first electrode 20 serves as a cathode, the cathode is preferably made of an electrode material such as metal, alloy, or electrically conductive compound that has a small work function, and a mixture thereof. Further, it is preferable that the cathode is made of material having a work function of 1.9 eV or more to 5 eV or less in order to limit a difference between the work function of the first electrode 20 and an LUMO (Lowest Unoccupied Molecular Orbital) level within an appropriate range. Examples of electrode material of the cathode include aluminum, silver, magnesium, gold, copper, chrome, molybdenum, palladium, tin, and alloy of these and other metal such as magnesium-silver mixture, magnesium-indium mixture, aluminum-lithium alloy and the like. The cathode may be formed of laminated film including a thin film made of aluminum and an ultrathin film (a thin film having a thickness of 1 nm or less so as to allow an electron to flow with tunneling injection) made of aluminum oxide, for example. Such an ultrathin film may be made of metal, metal oxide, or mixture of these and other metal. In a case where the cathode is designed as a reflecting electrode, it is preferable that the cathode be made of metal having high reflectance with respect to the light emitted from the light-emitting layer 32 and having a low resistivity, such as aluminum and silver. Note that, in a case where the first electrode 20 is the anode that serves as the electrode for injecting a hole (second carrier) treated as the second charge into the functional layer 30, the first electrode 20 is preferably made of metal having a large work function. Further it is preferable that the anode is made of material having a work function of 4 eV or more to 6 eV or less in order to limit a difference between a work function of the first electrode 20 and an HOMO (Highest Occupied Molecular Orbital) level within an appropriate range.

The material of the electrically-conductive polymer layer 39 of the second electrode 50 may be electrically conductive polymer material such as polythiophene, polyaniline, polypyrrole, polyphenylene, polyphenylenevinylene, polyacetylene, and polycarbazole. Alternatively electrically conductive polymer material for the electrically-conductive polymer layer 39 may be doped with a dopant such as sulfonate acid, Lewis acid, proton acid, alkali metal, alkali and earth metal, to improve the electric conductivity of the electrically-conductive polymer layer 39. In this respect, the electrically-conductive polymer layer 39 preferably has lower resistivity. In this regard, the electrical conductivity of the electrically-conductive polymer layer 39 in a lateral direction (in an in-plane direction) is improved with a decrease in the resistivity of the electrically-conductive polymer layer 39. Hence, it is possible to suppress the in-plane variation in the current flowing through the light-emitting layer 32, and therefore the luminance unevenness can be reduced.

The electrode part 48 of the patterned electrode 40 of the second electrode 50 is made of an electrode material including powder of metal and an organic binder. This metal may be silver, gold, or copper. Thus, in the organic electroluminescence element, since the electrode part 48 of the patterned electrode 40 of the second electrode 50 can have a resistivity and a sheet resistance that are lower than those of the second electrode 50 provided as a thin film made of the electrically conductive transparent oxide, the luminance unevenness can be reduced. Note that, the electrically conductive material used for of the patterned electrode 40 the second electrode 50 may be alloy, carbon black or the like, as substitute for metal.

For example, the patterned electrode 40 can be formed by printing, by a screen printing method or a gravure printing method, paste (printing ink) prepared by mixing metal powder with a set of an organic binder and an organic solvent. Examples of materials of the organic binder include acrylic resin, polyethylene, polypropylene, polyethylene terephthalate, polymethylmethacrylate, polystyrene, polyether sulfone, polyarylate, polycarbonate resin, polyurethane, polyacrylonitrile, polyvinyl acetal, polyamide, polyimide, diacryl phthalate resin, cellulosic resin, polyvinyl chloride, polyvinylidene chloride, polyvinyl acetate, other thermoplastic resin, and copolymer containing at least two of the above-listed resin components. Note that, the material of the organic binder is not limited thereto.

Material of the second extended wire 46 and the second terminal part 47 is the same as material of the patterned electrode 40 of the second electrode 50, but is not limited thereto. In a case where the material of the second extended wire 46 and the second terminal part 47 is the same as the material of the patterned electrode 40 of the second electrode 50, it is possible to form the second extended wire 46, the second terminal part 47, and the patterned electrode 40 at the same time. The second terminal part 47 may have either a single-layer structure or a multilayer structure.

Note that in the organic electroluminescence element of the present embodiment, the first electrode 20 has a thickness in a range of 80 nm to 200 nm, and the light-emitting layer 32 has a thickness in a range of 60 nm to 200 nm, and the second carrier transport layer 33 has a thickness in a range of 5 nm to 30 nm, the carrier injection layer 34 has a thickness in a range of 10 nm to 60 nm, and the electrically conductive polymer layer 39 has a thickness in a range of 200 nm to 400 nm. However, the aforementioned values are only examples and the thicknesses thereof are not limited particularly.

The patterned electrode 40 is formed into a grid shape (a net-like shape) as shown in FIGS. 1 to 3 and includes a plurality (six multiplied by six equals thirty-six, in the instance shown in FIG. 2) of openings 41. In this regard, in the patterned electrode 40 shown in FIG. 2, each opening 41 has a square shape in a plan view. In brief, the patterned electrode 40 shown in FIG. 2 is formed into a square grid shape.

With regard to the dimensions of the patterned electrode 40 in the second electrode 50 having a square grid shape, for example, a line width L1 (see FIG. 3) of the electrode part 48 in the patterned electrode 40 may be in a range of 1 μm to 100 μm, a height H1 (see FIG. 3) thereof may be in a range of 50 nm to 100 μm, and a pitch P1 (see FIG. 3) thereof may be in a range of 100 μm to 2000 μm. However, respective value ranges of the line width L1, the height H1 and the pitch P1 of the electrode part 48 of the patterned electrode 40 of the second electrode 50 are not definite particularly, but may be selected appropriately based on the size in the plan view of the element part 1 having the stack of the first electrode 20, the functional layer 30 and the second electrode 50. In this regard, to improve the use efficiency of the light produced in the light-emitting layer 32, it is preferable that the line width L1 of the electrode part 48 in the patterned electrode 40 of the second electrode 50 is decreased. In contrast, to suppress the luminance unevenness by decreasing the resistance of the second electrode 50, it is preferable that the line width L1 of the electrode part 48 in the patterned electrode 40 of the second electrode 50 is increased. Hence, it is preferable that the line width L1 is appropriately selected depending on the planar size of the organic electroluminescence element, for example. Further, it is preferable that the height H1 of the electrode part 48 in the patterned electrode 40 of the second electrode 50 is within a range of 100 nm to 10 μm. This range may be selected in view of: decreasing the resistance of the second electrode 50; improving the efficient use of the material (material use efficiency) of the patterned electrode 40 in a process of forming the patterned electrode 40 by a coating method such as a screen printing method; and selecting an appropriate radiation angle of the light emitted from the functional layer 30.

Furthermore, in the organic electroluminescence element, each opening 41 in the patterned electrode 40 may be formed into such an opening shape that an opening area is gradually increased with an increase in a distance from the functional layer 30. Thus, in the organic electroluminescence element, a spread angle of the light emitted from the functional layer 30 can be increased and therefore the luminance unevenness can be more reduced. Furthermore, in the organic electroluminescence element, it is possible to reduce a reflection loss and an absorption loss at the patterned electrode 40 of the second electrode 50. Therefore, the external quantum efficiency of the organic electroluminescence element can be more improved.

In a case where the patterned electrode 40 is formed into a grid shape, it is sufficient that the shape of each opening 41 in a plan view is a polygonal shape. In summary, the shape of each opening 41 in a plan view is not limited to a square shape, but may be a rectangular shape, an equilateral triangle shape, or a regular hexagonal shape, for example.

In a case where the opening shape of each opening 41 in a plan view is an equilateral triangle shape, the patterned electrode 40 is formed into a triangle grid shape. In a case where the opening shape of each opening 41 in a plan view is a regular hexagonal shape, the patterned electrode 40 is formed into a hexagonal grid shape (a honeycomb shape). Note that the shape of the patterned electrode 40 is not limited to a grid shape, but may be a comb shape, for example. The patterned electrode 40 may also be constituted by a set of two patterned electrodes each formed into a comb shape. Further, the number of openings 41 in the patterned electrode 40 is not particularly limited, but may be one or more. For example, in the case where the patterned electrode 40 has a comb shape or the patterned electrode 40 is constituted by two patterned electrodes each having a comb shape, the number of opening 41 can be one.

Further, the patterned electrode 40 may be formed to have such a planar shape as shown in FIG. 4, for example. That is, the patterned electrode 40 may be formed into such a shape in a plan view that the straight narrow line parts 44 of the electrode part 48 have the same line width and the opening area of the opening 41 is decreased by decreasing the interval between the adjacent narrow line parts 44 with an increase in a distance from the periphery of the patterned electrode 40. In the organic electroluminescence element, in a case where the patterned electrode 40 of the second electrode 50 is formed into the planar shape shown in FIG. 4, it is possible to improve the luminous efficiency of the second electrode 50 at the center of the patterned electrode 40 which is farther from the second terminal part 47 (see FIG. 1) than the periphery thereof is, in contrast to the case where the patterned electrode 40 is formed into the planar shape shown in FIG. 2. Consequently, the external quantum efficiency of the organic electroluminescence element can be improved. Further, in the organic electroluminescence element, since the patterned electrode 40 of the second electrode 50 is formed into the planar shape shown in FIG. 4, it is possible to suppress current crowding at a periphery of the functional layer 30 which is close to the first terminal part and the second terminal part 47, in contrast to a case where the patterned electrode 40 is formed into the planer shape shown in FIG. 2. Consequently, the lifetime of the organic electroluminescence element can be extended.

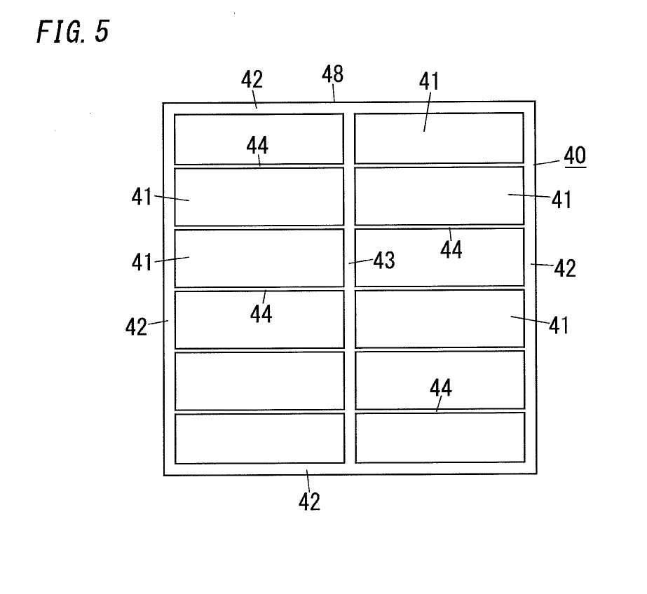

Further, the patterned electrode 40 of the second electrode 50 may be formed to have such a planar shape as shown in FIG. 5. In other words, the patterned electrode 40 is formed such that in a plan view widths of four first narrow line parts 42 defining the periphery of the electrode part 48 of the patterned electrode 40 and a width of a single second narrow line part 43 located at the center in a left and right direction of FIG. 5 are greater than a width of a narrow line part (third narrow line part) 44 located between the first narrow line part 42 and the second narrow line part 43. In the organic electroluminescence element, since the patterned electrode 40 of the second electrode 50 is formed into the planar shape shown in FIG. 5, it is possible to improve the luminous efficiency of the second electrode 50 at the center of the patterned electrode 40 which is farther from the second terminal part 47 (see FIG. 1) than the periphery thereof is, in contrast to a case where the patterned electrode 40 is formed into the planar shape shown in FIG. 2. Consequently, the external quantum efficiency of the organic electroluminescence element can be improved. Note that, in the case where the patterned electrode 40 is formed into the planar shape shown in FIG. 5, with increasing the heights of the first narrow line part 42 and the second narrow line part 43 having the relatively large widths so as to be greater than the height of the third narrow line part 44, it is possible to more decrease the resistances of the first narrow line part 42 and the second narrow line part 43.

The sealing substrate (sealing member) 80 functioning as a cover substrate is formed of a glass substrate, but is not limited to be formed thereof. For example, a plastic plate or the like may be used for the sealing substrate 80. Examples of materials of the glass substrate may include soda-lime glass and non-alkali glass. Examples of materials of the plastic plate may include polyethylene terephthalate, polyethylene naphthalene, polyether sulfone, and polycarbonate. Note that, in a case where the substrate 10 is formed of a glass substrate, it is preferable that the sealing substrate 80 is formed of a glass substrate made of the same material as the substrate 10.

A total light transmittance to visible light of the sealing substrate 80 is preferably equal to or more than 70%, but is not limited thereto. In view of improvement of the light-outcoupling efficiency of the organic electroluminescence element, it is preferable that the total light transmittance of the sealing substrate 80 is greater as possible. Note that the total light transmittance can be measured by means of a measurement method defined in ISO13468-1.

In the present embodiment, the sealing substrate 80 has a flat plate shape, but the shape of the sealing substrate 80 is not limited particularly. For example, the sealing substrate 80 may be provided with a recessed portion for accommodating the above element part 1 at a surface thereof facing the substrate 10, and the entire area surrounding the recessed portion within the facing surface may be bonded to the substrate 10. This configuration has an advantage that there is no need to prepare the frame part 100 provided as a separate part from the sealing substrate 80. In contrast, in a case where the sealing substrate 80 formed into a flat plate shape and the frame part 100 formed into a frame shape are provided as separate parts, there is an advantage that it is possible to use materials satisfying the respective requirements of an optical property (e.g., an optical transmittance and a refractive index) necessary for the sealing substrate 80 and a property (e.g., a gas barrier property) necessary for the frame part 100.

The frame part 100 and the surface of the substrate 10 are bonded to each other by means of a first bonding material. The first bonding material is epoxy resin, but is not limited thereto. For example, acrylic resin or the like can be used as the first bonding material. Epoxy resin, acrylic resin etc. used as the first bonding material may be ultraviolet-curing resin, thermosetting resin, or the like. Also, epoxy resin containing filler (made of e.g. silica, alumina) also can be used for the first bonding material. The frame part 100 is bonded in an airtight manner to the surface of the substrate 10 at the entire periphery of the surface of the frame part 100 facing the substrate 10. The frame part 100 and the sealing substrate 80 are bonded to each other by means of a second bonding material. The second bonding material is epoxy resin, but is not limited thereto. For example, acrylic resin, fritted glass or the like can be used as the second bonding material. Epoxy resin, acrylic resin etc. used as the second bonding material may be ultraviolet-curing resin, thermosetting resin, or the like. Also, epoxy resin containing filler (made of e.g. silica, alumina) also can be used for the second bonding material. The frame part 100 is bonded in an airtight manner to the sealing substrate 80 at the entire periphery of the surface of the frame part 100 facing the sealing substrate 80.

It is preferred that the organic electroluminescence element includes a light extraction structure (not shown) on an outer surface of the sealing substrate 80 (the opposite side of the sealing substrate 80 from the substrate 10) for suppressing reflection of the light emitted from the light-emitting layer 32 at the outer surface. For example, the above light extraction structure may be an uneven structure having a two-dimensional periodic structure. In a case where the wavelength of the light emitted from the light-emitting layer 32 falls within a range of 300 nm to 800 nm, the periodic length of such a two-dimensional periodic structure is preferably within a range of quarter to tenfold of a wavelength λ. The wavelength λ denotes the wavelength of the light in the medium (i.e. A is obtained by dividing the wavelength in vacuum by the refractive index of the medium). Such an uneven structure can be preliminarily formed on the outer surface with an imprint method such as a thermal imprint method (a thermal nanoimprint method) and a photo imprint method (a photo nanoimprint method). Furthermore, depending on the material of the sealing substrate 80 the sealing substrate 80 can be formed with injection molding. In this case, the uneven structure can be formed directly on the sealing substrate 80 by using a proper mold in a process of injection molding. Also, the uneven structure can be formed of a member separate from the sealing substrate 80. For example, the uneven structure can be constituted by a prismatic sheet (e.g. a light diffusion film such as LIGHT-UP GM3 (“LIGHT UP” is a registered trademark) available from KIMOTO CO., LTD.). The organic electroluminescence element of the present embodiment includes the light extraction structure and therefore it is possible to reduce the reflection loss of the light which is emitted from the light-emitting layer 32 and then strikes the outer surface of the sealing substrate 80. As a result, this configuration can improve the light extraction efficiency.

The insulating layer 60 may be of light curable resin (e.g., epoxy resin, acrylic resin and silicone resin) containing a hygroscopic agent.

Material of the hygroscopic agent is preferably alkali earth metal oxide or sulfate. Examples of the alkali earth metal oxide may include calcium oxide, barium oxide, magnesium oxide and strontium oxide. Examples of the sulfate may include lithium sulfate, sodium sulfate, gallium sulfate, titanium sulfate, and nickel sulfate. Examples of the material of the hygroscopic agent may include further calcium chloride, magnesium chloride, copper chloride, and magnesium oxide. Examples of the material of the hygroscopic agent also may include hygroscopic organic compounds such as silica gel and polyvinyl alcohol. The material of the hygroscopic agent is not limited to the above examples, but in these examples calcium oxide, barium oxide and silica gel are particularly preferable. Note that a rate of hygroscopic agent contained in the insulating layer 60 is not particularly limited.

The transparent protection layer 70 is made of polymeric organic material, and examples of material of the transparent protection layer 70 may include: electrically conductive polymer material such as polythiophene, polyaniline, polypyrrole, polyphenylene, polyphenylenevinylene, polyacetylene, and polycarbazole; and polymer material with a light transmissive property such as epoxy resin and acrylic resin. A preferable method of forming the transparent protection layer 70 is a coating method such as a spin coating method. A film made by a coating method may be cured by light or heat. A total light transmittance for visible light of the transparent protection layer 70 is preferably equal to or more than 70%, but is not limited thereto. In view of improvement of the light-outcoupling efficiency of the organic electroluminescence element, it is preferable that the total light transmittance is greater as possible. Note that the total light transmittance can be measured by means of a measurement method defined in ISO13468-1.

Alternatively, the transparent protection layer 70 may be made of inorganic material with a light transmissive property. Examples of such inorganic material may include electrical insulating material such as oxide silicon, silicon nitride, aluminum oxide (Al₂O₃) and transparent conductive oxide such as ITO and IZO. The transparent protection layer 70 can be formed by a coating method, for example. Such a coating method may be a spin coating method, a spray coating method, a dye coating method, a gravure printing method, or a screen printing method. In a case where the transparent protection layer 70 is formed by the coating method, an organic metallic compound (e.g. ethyl silicate of organic alkoxide) or polysilazane may be applied and then subjected to hydrolysis through heating or burning.

The transparent protection layer 70 can be formed by a physical deposition method such as vacuum vapor deposition method, ion plating, an ionized deposition method, a laser ablation method, and an arc plasma deposition method. Further, the transparent protection layer 70 may be formed by a chemical deposition method such as a chemical vapor deposition method, a plasma chemical vapor deposition method, a metal organic chemical vapor deposition method and a spraying method. The transparent protection layer 70 can also be formed by other methods such as Langmuir-Blodgett method (LB method), a sol-gel method, and plating.

In a case where the physical deposition method is used for forming the transparent protection layer 70, in consideration of suppressing damages to the electrically-conductive polymer layer 39, it is preferable to use a deposition device and a deposition condition enabling formation of films with less energy. The deposition energy can be calculated, for example, through an analysis of kinetic energy of gas molecules (molecules of deposition material) in an atmosphere for deposition by use of the energy analyzer of Model No. PPM442 available from Pfeiffer Vacuum GmbH. In this regard, in a case where as with sputtering the deposition material (material for forming films) and material (e.g., argon and oxygen) other than the deposition material coexist in the atmosphere for deposition, the deposition energy is defined as energy of a molecule that is the highest in energy of molecules in the atmosphere. In order to suppress the deposition energy, it is preferable to employ a resistance heating vapor deposition method, an electron beam vapor deposition method, or a laser heating vapor deposition method, for example. With respect to sputtering, in order to suppress the deposition energy it is preferable to employ facing targets sputtering or parallel plate magnetron sputtering at lower voltage, for example. Further, when sputtering is parallel plate DC sputtering, the deposition energy can be decreased by using other gas (e.g. krypton gas and xenon gas) than argon gas as sputtering gas, increasing high pressure for deposition, or increasing a distance between a target and the electrically-conductive polymer layer 39.

With regard to the organic electroluminescence element, forming the transparent protection layer 70 by coating in the manufacturing process can suppress damages to the electrically-conductive polymer layer 39 in the formation of the transparent protection layer 70 relative to forming the transparent protection layer 70 by physical deposition or chemical deposition. Therefore the property of the element can be improved.

It is preferable that the transparent protection layer 70 has a refractive index greater than at least one of a refractive index of the light-emitting layer 32 and a refractive index of the electrically conductive polymer layer 39 of the second electrode 50. Thereby, the light-outcoupling efficiency of the organic electroluminescence element can be improved.

Material of the resin layer 90 is acrylic resin, but is not limited thereto. The resin layer 90 may be made of epoxy resin, ultraviolet-curable resin or thermosetting resin, for example. Further, the material of the resin layer 90 preferably has a refractive index greater than a refractive index of the material of the electrically-conductive polymer layer 39 of the second electrode 50, and thus, for example, imide resin prepared to have a great refractive index can be used as the material of the electrically-conductive polymer layer 39.

In a case where the second electrode 50 is constituted by at least the electrically-conductive polymer layer 39 as with the organic electroluminescence element of the present embodiment, the electrically-conductive polymer layer 39 is likely to be damaged in the process of depositing the transparent protection layer 70 by sputtering when the transparent protection layer 70 is made of not polymeric organic material but inorganic oxide or inorganic nitride. As a result, unfortunately the lifetime of the organic electroluminescence element may be shortened or reliability of the organic electroluminescence element may be decreased.

In contrast, in the organic electroluminescence element of the present embodiment, the second electrode 50 is constituted by at least the electrically-conductive polymer layer 39 which is in contact with the functional layer 30 and has a light transmissive property. Further, the organic electroluminescence element of the present embodiment includes: the sealing substrate 80 which is opposite the surface of the substrate 10 and has a light transmissive property; the transparent protection layer 70 covering the element part 1 which has the stack of the first electrode 20, the functional layer 30 and the second electrode 50; and the resin layer 90 which is interposed between the transparent protection layer 70 and the sealing substrate 80 and has a light transmissive property. In this regard, in the organic electroluminescence element of the present embodiment, the transparent protection layer 70 is made of polymeric organic material with a light transmissive property. The organic electroluminescence element of the present embodiment includes the resin layer 90 and therefore the light-outcoupling efficiency can be improved. Further, the organic electroluminescence element of the present embodiment includes the transparent protection layer 70 made of polymeric organic material and thus the reliability can be improved. Further, the organic electroluminescence element includes the patterned electrode 40 located on the opposite side of the electrically conductive polymer layer 39 from the functional layer 30 and having the openings 41 for allowing light from the functional layer 30 to pass therethrough and the electrode part 48 of the patterned electrode 40 is made of electrode material including metal powder and an organic binder. Consequently, the organic electroluminescence element of the present embodiment can reduce the luminance unevenness.

The transparent protection layer 70 preferably has a thickness in a range of 10 nm to 100 nm inclusive.

In order to improve the light-outcoupling efficiency of the organic electroluminescence element, the transparent protection layer 70 preferably has a refractive index higher (greater) than a refractive index of the electrically conductive polymer layer 39. However, as described above, it is extremely difficult to design resin material that has a high refractive index and can reduce influence on the electrically conductive polymer layer 39. Therefore, in the organic electroluminescence element of the present embodiment, the transparent protection layer 70 is thinned in order to reduce influence of the transparent protection layer 70 on the optical property of the organic electroluminescence element. Specifically, it is preferable that the transparent protection layer 70 has a thickness equal to or less than 100 nm.

Meanwhile, in a case where the transparent protection layer 70 has a thickness less than 10 nm, depending on the material of the resin layer 90, there may arise negative effects such as spreading of low-molecular components into the electrically-conductive polymer layer 39 through the transparent protection layer 70 and insufficient functioning of the transparent protection layer 70 as a protection layer due to minuscule cracks in the transparent protection layer 70 or an uneven film thickness of the transparent protection layer 70. Hence, the transparent protection layer 70 preferably has a thickness equal to or more than 10 nm.

As mentioned above, when the transparent protection layer 70 of the organic electroluminescence element has a thickness in a range of 10 nm to 100 nm inclusive, it is possible to drastically reduce influence on the electrically-conductive polymer layer 39 in the process of forming the resin layer 90. Therefore, in the organic electroluminescence element, it becomes possible to select and design the material of the resin layer 90 without consideration of influence of the resin layer 90 on the electrically-conductive polymer layer 39. In other words, in the organic electroluminescence element, it becomes possible to independently select and design the material of the resin layer 90 according to required properties of the resin layer 90 such as a relatively high refractive index, without consideration of interaction between the material of the resin layer 90 and the material of the electrically-conductive polymer layer 39. Note that, the organic electroluminescence element including the transparent protection layer 70 made of inorganic material can achieve the same effect as the organic electroluminescence element including the transparent protection layer 70 made of resin material.

To prevent intrusion of gas such as moisture from outside, the transparent protection layer 350 (see FIG. 8) serving as a gas barrier layer as disclosed in document 3 is required to have, for example, a thickness of 0.1 μm to 3 μm (see [0045] in document 3). However, in the organic electroluminescence element of the present embodiment, the transparent protection layer 70 is intended to reduce influence of the material of the resin layer 90 on the electrically-conductive polymer layer 39 in the process of forming the resin layer 90. Therefore, in the organic electroluminescence element of the present embodiment, even when the transparent protection layer 70 has a thickness equal to or less than 100 nm, it is possible to enjoy the benefit derived from the presence of the transparent protection layer 70. Further, in the organic electroluminescence element of the present embodiment, with making the thickness of the transparent protection layer 70 equal to or less than 100 nm, it becomes possible to reduce influence of the transparent protection layer 70 on the optical properties of the organic electroluminescence element. In addition, in the organic electroluminescence element, with setting the refractive index of the resin layer 90 so as to be greater than the refractive index of the electrically-conductive polymer layer 39, it becomes possible to improve the light-outcoupling efficiency.

Note that, in the organic electroluminescence element of the present embodiment, hygroscopic agent may be contained in region of the resin layer 90 which does not contribute to the light-outcoupling efficiency. Consequently, in the organic electroluminescence element of the present embodiment, it becomes possible to suppress intrusion of moisture to the element part 1 more. That is, in the organic electroluminescence element of the present embodiment, it becomes possible to improve a gas barrier property more. The organic electroluminescence element can employ any of various configurations for improving the gas barrier property, and it is not necessary to employ such a configuration that the transparent protection layer 350 is formed as a gas barrier layer to cover the transparent electrode 340 and the like as shown in document 3. In contrast, the present invention is intended to solve a new problem specific to such a structure that an electrically conductive polymer is used as material of an electrode allowing light transmission, and has different structure and effect from a conventional organic electroluminescence element including a gas barrier layer.

The organic electroluminescence element described in the above embodiment is suitable for lighting, but not limited thereto and available for other purposes.

Note that, the figures used for describing the above embodiment are schematic ones, and do not necessarily show the actual ratio of the length, thickness, or the like of the components.

### EXAMPLES

### Example 1

The organic electroluminescence element having the structure as shown in FIG. 1 was manufactured as Example 1.

Manufacturing conditions of the organic electroluminescence element of Example 1 are as follows.

To manufacture the organic electroluminescence element of Example 1, the first step was performed. In the first step, first a non-alkali glass plate (No. 1737 available from Corning Incorporated) with a thickness of 0.7 mm was prepared as the substrate 10 and a cathode serving as the first electrode 20 of aluminum film having a thickness of 80 nm was formed on the surface of the substrate 10 by a vacuum vapor deposition method.

After the first step, the second step of forming the functional layer 30 was performed. In the second step, the light-emitting layer 32, the hole transport layer serving as the carrier transport layer 33, and the hole injection layer serving as the carrier injection layer 34 were formed sequentially.

In the process of forming the light-emitting layer 32, the first electrode 20 was coated, with a spin coater, with a solution prepared by dissolving 1 wt % of red polymeric material (“Light Emitting polymer ATS111RE” available from American Dye Source, Inc.) in THF solvent to form a film with a thickness of about 200 nm and then the film was burned at 100 degrees Celsius for ten minutes to give the light-emitting layer 32. Note that the light-emitting layer 32 has a refractive index of about 1.8 for light with the peak wavelength of the emission spectrum of the light-emitting layer 32.

In the process of forming the hole transport layer serving as the carrier transport layer 33, first the light-emitting layer 32 was coated, with a spin coater, with a solution prepared by dissolving 1 wt % of TFB (“Hole Transport Polymer ADS259BE” available from American Dye Source, Inc.) in THF solvent to form a TFB coating with a thickness of about 12 nm and then the TFB coating was burned at 200 degrees Celsius for ten minutes to give the hole transport layer. Note that the hole transport layer has a refractive index of about 1.8.

In the process of forming the hole injection layer serving as the second carrier injection layer 34, the hole transport layer was coated, with as spin coater, with a mixture of an equal amount of PEDOT-PSS (“CLEVIOUS PVP AI4083” available from Heraeus Precious Metals GmbH & Co. KG, PEDOT:PSS=1:6) and isopropyl alcohol to form a film of PEDOT-PSS with a thickness of about 100 nm and then the film was burned at 150 degrees Celsius for ten minutes to give the hole injection layer as the second carrier injection layer 34. Note that the hole injection layer has a refractive index of about 1.5.

After the second step, the third step of forming the electrically-conductive polymer layer 39 was performed. In the third step, highly electrically conductive PEDOT-PSS (“CLEVIOUS SHT” available from Heraeus Precious Metals GmbH & Co. KG) was applied by a screen printing method and then heated at 130 degrees Celsius for thirty minutes in a nitrogen atmosphere to give the electrically-conductive polymer layer 39. Note that the electrically-conductive polymer layer 39 has a refractive index of about 1.46 for light with the peak wavelength of the emission spectrum of the light-emitting layer 32.

After the third step, the fourth step of forming the insulating layer 60 was performed. In the fourth step, imide resin (“HR11783” available from OPTMATE Corporation, refractive index of 1.78, concentration of 18%) was applied by use of a screen as a mask and then heated at 130 degrees Celsius for thirty minutes in a nitrogen atmosphere to give the insulating layer 60.

After the fourth step, the fifth step of forming the patterned electrode 40 was performed. In the fifth step, Ag paste was applied by use of a screen having a line width of 50 μm and a space width of 500 μm as a mask and then heated at 130 degrees Celsius for thirty minutes in a nitrogen atmosphere to give the patterned electrode 40. In the fifth step, the patterned electrode 40 was formed in such alignment that the patterned electrode 40 overlapped the insulating layer 60 in the thickness direction. Note that the screen used in the fifth step had openings to form the first extended wire, the first terminal part, the second extended wire 46 and the second terminal part 47, respectively. In brief, in the present example, in the fifth step, the first extended wire, the first terminal part, the second extended wire 46 and the second terminal part 47 were formed in addition to the patterned electrode 40. Note that in the organic electroluminescence element of Example 1 the second electrode 50 including the electrically-conductive polymer layer 39 and the patterned electrode 40 serves as an anode.

After the fifth step, the sixth step of forming the transparent protection layer 70 was performed. In the sixth step, PEDOT-PSS((“CLEVIOUS PVP AI4083” available from Heraeus Precious Metals GmbH & Co. KG) was applied to form a film with a thickness of 100 nm and then the film was burned at 180 degrees Celsius for ten minutes to give the transparent protection layer 70. Note that the transparent protection layer 70 has a refractive index of about 1.54 for light with the peak wavelength of the emission spectrum of the light-emitting layer 32.

In the manufacture of the organic electroluminescence element of Example 1, the seventh step was performed after the first to sixth steps were completed. In the seventh step, first the substrate 10 was transported into a glove box in a dry nitrogen atmosphere having a dew point of −80 degrees Celsius without exposed to the air. Meanwhile, sealant of ultraviolet-curable epoxy resin was applied to the frame part 100 serving as a cover cap made of non-alkali glass including the sealing substrate 80 and the frame part 100 integrally and further the cover cap was filled with ultraviolet-curable acrylic resin used as material of the resin layer 90 by casting. And then, in the glove box, the cover cap was placed on the substrate 10 via the sealant such that the cover cap and the substrate enclose the element part 1 and the sealant was cured with ultraviolet irradiation. As a result the organic electroluminescence element was obtained. Note that the sealing substrate 80 has a refractive index of about 1.5 for light with the peak wavelength of the emission spectrum of the light-emitting layer 32. Also, the resin layer 90 has a refractive index of about 1.51 for light with the peak wavelength of the emission spectrum of the light-emitting layer 32.

### Example 2

The organic electroluminescence element of Example 2 was prepared to have the same structure as the organic electroluminescence element of Example 1, except the transparent protection layer 70 of the present example had a thickness of 40 nm.

### Example 3

The organic electroluminescence element of Example 3 was prepared to have the same structure as the organic electroluminescence element of Example 1, except the transparent protection layer 70 of the present example had a thickness of 25 nm.

### Example 4

The organic electroluminescence element of Example 4 was prepared to have the same structure as the organic electroluminescence element of Example 1, except the transparent protection layer 70 of the present example was of polysilazane and had a thickness of 90 nm.

In the sixth step of forming the transparent protection layer 70, polysilazane (“Aquamica NL120” available from AZ Electronic Materials S.A.) was applied to form a film with a thickness of 90 nm and then burned at 150 degrees Celsius for thirty minutes to give the transparent protection layer 70 made of oxide silicon of inorganic material. Note that the transparent protection layer 70 has a refractive index of about 1.48 for light with the peak wavelength of the emission spectrum of the light-emitting layer 32.

### Comparative Example 1

The organic electroluminescence element of the first comparison example was prepared to have the same structure as that of the organic electroluminescence element of Example 1, except the organic electroluminescence element of the present comparative example did not include the transparent protection layer 70.

### Comparative Example 2

The organic electroluminescence element of comparative Example 2 was prepared to have the same structure as the organic electroluminescence element of Example 1, except the organic electroluminescence element of the present comparative example did not include the resin layer 90.

Following Table 1 shows a result of measurement of the light-outcoupling efficiency and the front luminance with respect to each of Example 1 and Comparative Example 1.

TABLE 1

| | Transparent protection layer | | | | | |
|---|---|---|---|---|---|---|
| | Presence | | | | | Front |
| | or | | Film | Resin | Light-outcoupling | luminance |
| | absence | Material | thickness | layer | efficiency ratio | ratio |
| Example 1 | presence | polymeric | 100 nm | presence | 2.4 | 0.98 |
| | | material | | | | |
| Example 2 | presence | polymeric | 40 nm | presence | 2.3 | 0.96 |
| | | material | | | | |
| Example 3 | presence | polymeric | 25 nm | presence | 2.4 | 0.97 |
| | | material | | | | |
| Example 4 | presence | inorganic | 90 nm | presence | 2.5 | 1.03 |
| | | material | | | | |
| Comparative | absence | | 0 nm | presence | 2.2 | 0.55 |
| Example 1 | | | | | | |
| Comparative | absence | | 0 nm | absence | 1.0 | 1.00 |
| Example 2 | | | | | | |

In Table 1, for each of Examples 1 to 4 and Comparative Example 1, the “light-outcoupling efficiency ratio” is defined as a ratio of the light-outcoupling efficiency of the organic electroluminescence element to the light-outcoupling efficiency of the organic electroluminescence element of Comparative Example 2 of 1.0. Further, in the Table 1, “front luminance ratio” indicates a ratio of “front luminance of the organic electroluminescence element that is measured after the organic electroluminescence element is left in an N2 gas atmosphere for twenty four hours after the organic electroluminescence element is prepared” to “front luminance of the organic electroluminescence element that is measured immediately after the organic electroluminescence element is prepared”.

In the measurement of the light-outcoupling efficiency of each of the organic electroluminescence elements of Examples 1 to 4 and Comparative Examples 1 and 2, a hemispherical lens of glass was situated on the light emission surface of the sealing substrate 80 with matching oil in between. The total radiant flux emerging from the hemispherical lens was measured with an integrating sphere while a constant current with a current density of 10 mA/cm² was supplied between the second terminal part 47 and the first terminal part from a DC power supply (trade name “2400” available from Keithley Instruments, Inc.). Based on this measurement result, the light-outcoupling efficiency was calculated. In the measurement of the front luminance of each of the organic electroluminescence elements of Examples 1 to 4 and Comparative Examples 1 and 2, luminance at the angle of 0° was measured with a luminance meter (trade name “SR-3” available from Topcon corporation) while a constant current with a current density of 10 mA/cm² was supplied between the second terminal part 47 and the first terminal part from a DC power supply (trade name “2400” available from Keithley Instruments, Inc.).

Table 1 shows that the light-outcoupling efficiencies of the organic electroluminescence elements of Examples 1 to 4 are greater than those of the organic electroluminescence elements of Comparative Examples 1 and 2. Further, it is also found that the stability (temporal stability) of the element property of each of the organic electroluminescence elements of Examples 1 to 4 is better than that of the organic electroluminescence element of Comparative Example 1.

It is also found that the organic electroluminescence elements of Examples 1 to 4 have almost the same front luminance ratio as Comparative Example 2. This result shows that even when the transparent protection layer 70 has a thickness of about 25 nm, the transparent protection layer 70 can prevent the influence on the electrically-conductive polymer layer 39 which would be caused by of the resin layer 90.

Further, the light-outcoupling efficiency ratio and the front luminance ratio of the organic electroluminescence element of Example 4 are almost equal to or slightly better than those of the organic electroluminescence elements of Examples 1 to 3. This result shows that the transparent protection layer 70 made of inorganic material with a light transmissive property can produce the same or similar effect as the transparent protection layer 70 made of polymeric organic material with a light transmissive property.

1. An organic electroluminescence element comprising:
a substrate;
a first electrode disposed on/above a surface of the substrate;
a second electrode facing an opposite side of the first electrode from the surface of the substrate; and
a functional layer which is interposed between the first electrode and the second electrode and includes at least a light-emitting layer,
the organic electroluminescence element being configured to allow light to emerge from the second electrode,
the second electrode including at least an electrically conductive polymer layer which is in contact with the functional layer and has a light transmissive property,
the organic electroluminescence element further comprising:
a sealing substrate which is opposite the surface of the substrate and has a light transmissive property;
a transparent protection layer covering an element part which has a stack of the first electrode, the functional layer and the second electrode; and
a resin layer which is interposed between the transparent protection layer and the sealing substrate and has a light transmissive property.

2. The organic electroluminescence element according to claim 1, wherein
the transparent protection layer has a thickness in a range of 10 nm to 100 nm inclusive.

3. The organic electroluminescence element according to claim 1, wherein
the resin layer has a refractive index greater than a refractive index of the electrically conductive polymer layer.

4. The organic electroluminescence element according to claim 1, wherein
the transparent protection layer is formed by a coating method.

5. The organic electroluminescence element according to claim 1, wherein
the transparent protection layer is made of polymeric organic material with a light transmissive property.

6. The organic electroluminescence element according to claim 1, wherein
the transparent protection layer is made of inorganic material with a light transmissive property.

7. The organic electroluminescence element according to claim 1, wherein:
the second electrode includes a patterned electrode;
the patterned electrode includes
an electrode part covering a surface on an opposite side of the electrically conductive polymer layer from the functional layer, and
an opening formed in the electrode part such that the surface of the electrically conductive polymer layer is exposed through the opening; and
the electrode part of the patterned electrode is made of electrode material including metal powder and an organic binder.

8. The organic electroluminescence element according to claim 1, wherein
the transparent protection layer has a refractive index greater than at least one of a refractive index of the light-emitting layer and a refractive index of the electrically conductive polymer layer.
